(19) United States
(12) Patent Application Publication
(10) Pub. No.: US 2020/0280295 A1
(43) Pub. Date: Sep. 3, 2020

(54) LOW NOISE T-COIL PAIR DESIGN FOR DIFFERENTIAL INPUT/OUTPUT (I/O) CIRCUITS

(71) Applicant: QUALCOMM Incorporated, San Diego, CA (US)

(72) Inventors: Siqi FAN, San Diego, CA (US); Li SUN, Irvine, CA (US); Dong REN, San Diego, CA (US); Miao LI, San Diego, CA (US); Jie XU, San Diego, CA (US)

(21) Appl. No.: 16/452,003

(22) Filed: Jun. 25, 2019

Related U.S. Application Data
(60) Provisional application No. 62/812,781, filed on Mar. 1, 2019.

(51) Int. Cl. H03H 5/00

(52) U.S. Cl. CPC H03H 5/00

(57) ABSTRACT

Aspects of the disclosure are directed to a low noise T-coil design. In accordance with one aspect, an input/output (I/O) circuit includes a first T-coil, wherein the first T-coil includes a first set of two inductors connected to each other in series arranged to accommodate a first current flow to produce a first magnetic field with a first perpendicular direction; and a second T-coil, wherein the second T-coil includes a second set of two inductors connected to each other in series arranged to accommodate a second current flow to produce a second magnetic field with a second perpendicular direction; and wherein the second magnetic field cancels the first magnetic field.

### CLAIM OF PRIORITY UNDER 35 U.S.C. § 119

The present Application for Patent claims priority to Provisional Application No. 62/812,781 entitled “LOW NOISE T-COIL PAIR DESIGN FOR DIFFERENTIAL INPUT/OUTPUT (I/O) CIRCUITS” filed Mar. 1, 2019, and assigned to the assignee hereof and hereby expressly incorporated by reference herein.

### TECHNICAL FIELD

This disclosure relates generally to the field of T-coil design, and, in particular, to low noise T-coil design.

### BACKGROUND

High speed input/output (I/O) circuits are commonly used to receive high rate signals at an input to a functional circuit and to transmit high rate signals at an output of another functional circuit. In some cases, high speed I/O circuits are susceptible to electrostatic discharge (ESD) effects. For example, ESD effects may be mitigated by incorporating additional circuit elements in the high speed I/O circuits, such as ESD capacitors. Capacitors are electrical circuit elements which have capacitance (i.e., an ability to store electric energy). However, high speed I/O circuit performance may be affected by bandwidth limitations due to capacitive loading effects from the ESD capacitors. A T-coil design for high speed I/O circuits is desired.

### SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

In one aspect, the disclosure provides a T-coil design for high speed I/O circuits. Accordingly, a method for implementing a low noise T-coil design including implementing a first T-coil in a circuit layer with a first current flow in an outward spiral direction to produce a first magnetic field with a first perpendicular direction; implementing a second T-coil in the circuit layer with a second current flow in an inward spiral direction to produce a second magnetic field with a second perpendicular direction; connecting the first T-coil to a first differential interface; and connecting the second T-coil to a second differential interface, wherein the second magnetic field cancels the first magnetic field. In one example, the circuit layer is a conductive layer. In one example, the circuit layer is an aluminum layer.

In one example, the method further includes implementing the circuit layer for an integrated circuit (IC). In one example, the method further includes connecting the first T-coil to a first circuit interface; and connecting the second T-coil to a second circuit interface.

In one example, the first circuit interface is connected to a first load interface. In one example, the second circuit interface is connected to a second load interface. In one example, the first perpendicular direction is out of the circuit layer and the second perpendicular direction is into the circuit layer.

In one example, the first T-coil is arranged as a first spiral inductor. In one example, the first T-coil includes a first top half and a first bottom half, and wherein the first T-coil includes a first terminal connected to the first bottom half and includes a second terminal connected to the first top half. In one example, the second T-coil is arranged as a second spiral inductor. In one example, the second T-coil includes a second top half and a second bottom half, and wherein the second T-coil includes a first terminal connected to the second bottom half and includes a second terminal connected to the second top half. In one example, the first T-coil is connected to the first differential interface via a first bump connection.

In one example, the first differential interface serves as a first input port. In one example, the first input port is connected to a signal source via a first input transmission line. In one example, the first differential interface serves as a first output port. In one example, the first output port is connected to a signal destination via a first output transmission line.

Another aspect of the disclosure provides an input/output (I/O) circuit including a first T-coil, wherein the first T-coil includes a first set of two inductors connected to each other in series arranged to accommodate a first current flow to produce a first magnetic field with a first perpendicular direction; and a second T-coil, wherein the second T-coil includes a second set of two inductors connected to each other in series arranged to accommodate a second current flow to produce a second magnetic field with a second perpendicular direction; and wherein the second magnetic field cancels the first magnetic field.

In one example, the input/output (I/O) circuit further includes a first middle node located between two inductors of the first set of two inductors; and a first electrostatic discharge (ESD) capacitor coupled to the first T-coil at the first middle node. In one example, the input/output (I/O) circuit further includes a second middle node located between two inductors of the second set of two inductors; and a second electrostatic discharge (ESD) capacitor coupled to the second T-coil at the second middle node.

In one example, the first T-coil further includes a first bridge capacitor connected in parallel to the first set of two inductors. In one example, the second T-coil further includes a second bridge capacitor connected in parallel to the second set of two inductors. In one example, the first T-coil further includes a first terminal and a second terminal, wherein the first terminal is a polarity reference for the first T-coil and the second terminal is an inverse polarity reference for the first T-coil. In one example, the first bridge capacitor is connected to the first terminal and the second terminal.

In one example, the second T-coil further includes a third terminal and a fourth terminal, wherein the third terminal is a polarity reference for the second T-coil and the fourth terminal is an inverse polarity reference for the second T-coil. In one example, the second bridge capacitor is connected to the third terminal and the fourth terminal.

Another aspect of the disclosure provides a computer-readable medium storing computer executable code, operable on a device including at least one processor and at least one memory coupled to the at least one processor, wherein the at least one processor is configured to implement a low noise T-coil design, the computer executable code including instructions for causing a computer to implement a first T-coil in a circuit layer with a first current flow in an outward spiral direction to produce a first magnetic field with a first perpendicular direction; instructions for causing the computer to implement a second T-coil in the circuit layer with a second current flow in an inward spiral direction to produce a second magnetic field with a second perpendicular direction; instructions for causing the computer to connect the first T-coil to a first differential interface; and instructions for causing the computer to connect the second T-coil to a second differential interface, wherein the second magnetic field cancels the first magnetic field.

In one example, the computer-readable medium further includes instructions for causing the computer to connect the first T-coil to a first circuit interface and to connect the second T-coil to a second circuit interface. In one example, the computer-readable medium further includes instructions for causing the computer to connect the first circuit interface to a first load interface and to connect the second circuit interface to a second load interface. In one example, the computer-readable medium further includes instructions for causing the computer to implement the circuit layer for an integrated circuit (IC).

These and other aspects of the present disclosure will become more fully understood upon a review of the detailed description, which follows. Other aspects, features, and implementations of the present disclosure will become apparent to those of ordinary skill in the art, upon reviewing the following description of specific, exemplary implementations of the present invention in conjunction with the accompanying figures. While features of the present invention may be discussed relative to certain implementations and figures below, all implementations of the present invention can include one or more of the advantageous features discussed herein. In other words, while one or more implementations may be discussed as having certain advantageous features, one or more of such features may also be used in accordance with the various implementations of the invention discussed herein. In similar fashion, while exemplary implementations may be discussed below as device, system, or method implementations it should be understood that such exemplary implementations can be implemented in various devices, systems, and methods.

### BRIEF DESCRIPTION OF THE DRAWINGS

FIG. 1 illustrates an example input network of an input/output (I/O) circuit with electrostatic discharge (ESD) protection.

FIG. 2 illustrates an example T-coil with a first inductor and a second inductor connected in series.

FIG. 3 illustrates an example input network of an input/output (I/O) circuit with electrostatic discharge (ESD) protection and a T-coil.

FIG. 4 illustrates an example frequency-domain comparison between a first input/output (I/O) circuit without a T-coil and a second input/output (I/O) circuit with a T-coil for a signal with 16 gigabit/sec (Gb/s) rate.

FIG. 5 illustrates an example time-domain comparison between a first input/output (I/O) circuit without a T-coil and a second input/output (I/O) circuit with a T-coil for a signal with 16 Gb/s rate.

FIG. 6 illustrates an example circuit layout with a plurality of input/output (I/O) circuits.

FIG. 7 illustrates a first example T-coil arrangement for an input/output (I/O) circuit.

FIG. 8 illustrates an example current graph for an aggressor current pulse with a 20 milliampere (mA) amplitude at a TX circuit.

FIG. 9 illustrates an example voltage graph for a victim voltage with a +/−60 millivolt differential ripple voltage at a RX circuit.

FIG. 10 illustrates a second example T-coil arrangement for an input/output (I/O) circuit.

FIG. 11 illustrates a third example T-coil arrangement for an input/output (I/O) circuit.

FIG. 12 illustrates an example voltage graph comparing two T-coil designs.

FIG. 13 illustrates a first embodiment of a low noise T-coil design on a circuit layer.

FIG. 14 illustrates an example detailed view of the low noise T-coil design on the circuit layer shown in FIG. 13.

FIG. 15 illustrates a second embodiment of a low noise T-coil design on a circuit layer.

FIG. 16 illustrates an example detailed view of the low noise T-coil design on the circuit layer shown in FIG. 15.

FIG. 17 illustrates an example flow diagram for creating a low noise T-coil design.

FIG. 18 illustrates an example electrical schematic diagram for an input/output (I/O) circuit with ESD protection and a low noise T-coil design.

FIG. 19 illustrates an example schematic diagram for the first example T-coil arrangement shown in FIG. 8.

FIG. 20 illustrates an example schematic diagram for the second example T-coil arrangement shown in FIG. 10 and the third example T-coil arrangement shown in FIG. 11.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

While for purposes of simplicity of explanation, the methodologies are shown and described as a series of acts, it is to be understood and appreciated that the methodologies are not limited by the order of acts, as some acts may, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

An example technique to improve I/O circuit performance is through equalization, for example, by adding inductors to compensate for the capacitors. Inductors are electrical circuit elements which have inductance (i.e., an ability to store magnetic energy). One form of equalization uses a T-coil which has two inductors connected in series and a bridge capacitor. In one aspect, for multi-lane applications with multiple I/O circuits, electromagnetic coupling among various T-coils may affect performance due to spatial proximity of the T-coils and due to limited spacing to an outer conductive perimeter (e.g., seal ring). In one aspect, a low noise T-coil design for high speed I/O circuits is disclosed herein.

In one aspect, high speed input/output (I/O) circuits need to balance several properties for optimal performance. For example, a higher symbol rate in the I/O circuit may support a higher rate signal but may require a wide bandwidth. That is, I/O circuits may require wide bandwidth to support high rate signals. In addition, electrostatic discharge (ESD) capacitors may be needed in the I/O circuits for protection against ESD events. However, usage of ESD capacitors may load an impedance in the I/O circuits and thus reduce the bandwidth of the I/O circuits. In addition, the I/O circuits may be integrated onto a very small area (e.g., an integrated circuit) with multiple I/O circuits in close proximity. That is, I/O circuits may be susceptible to undesired voltage coupling due to their close proximity. Thus, achieving multiple high speed I/O circuits with ESD protection in a small area may require balancing bandwidth needs and spatial constraints.

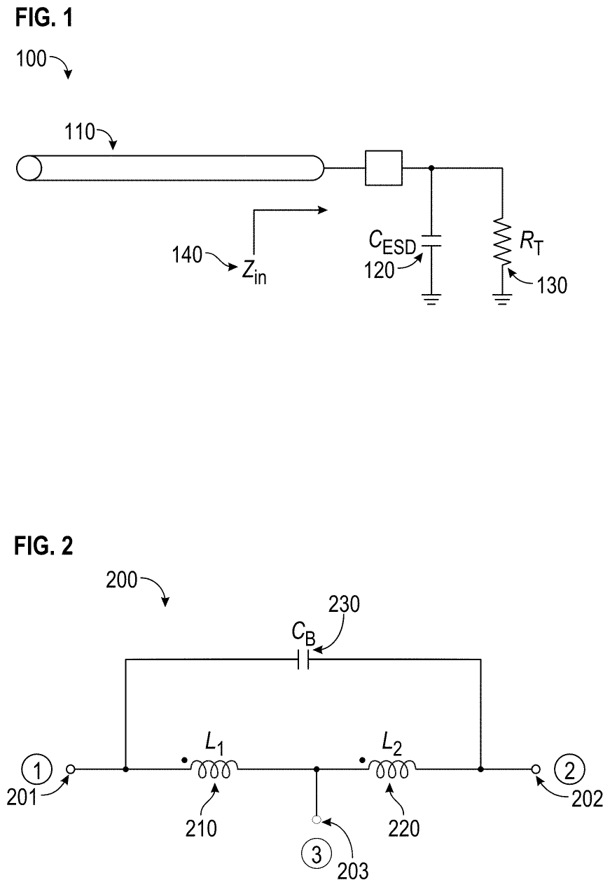

FIG. 1 illustrates an example network 100 of an input/output (I/O) circuit with electrostatic discharge (ESD) protection. For example, an input signal from a signal source may be conveyed on transmission line 110 which may be terminated by an ESD capacitor 120 with capacitance C_{ESD} and an input resistor 130 with resistance R_{T}. For example, an input impedance Zᵢₙ 140 of the network 100 may be expressed as

Zᵢₙ=R_{T}/(1+sC_{ESD}R_{T}),

where s=jω is a complex frequency, ω is a radial frequency (rad/sec) and j is an imaginary unit (i.e., j=√−1). For example, a first bandwidth (e.g., in rad/sec) of the input impedance Zᵢₙ 140 may be expressed as ω₁=1/(R_{T} C_{ESD}). For example, the first bandwidth ω₁ decreases as the capacitance C_{ESD} increases. In one example, increasing the capacitance C_{ESD} increases ESD protection. That is, as ESD protection is increased, the first bandwidth is reduced, which may compromise (e.g., degrade) the input signal. In one example, bandwidth may be expressed either in rad/sec or in Hertz (Hz) since 1 Hz is equivalent to 2π rad/sec. In another example, an output signal to a signal destination may be conveyed on transmission line 110.

FIG. 2 illustrates an example T-coil 200 with a first inductor 210 and a second inductor 220 connected in series. For example, a first terminal 201 of the T-coil 200 is connected to the first inductor 210 on a first inductor polarity reference and a second terminal 202 of the T-coil 200 is connected to the second inductor 220 on a second inductor inverse polarity reference. For example, a third terminal 203 of the T-coil 200 is connected to the first inductor 210 on a first inductor inverse polarity reference and to the second inductor 220 on a second inductor polarity reference. In one example, a polarity reference refers to a first inductor terminal where a voltage has a same sign as a derivative of a current into the first inductor terminal In one example, an inverse polarity reference refers to a second inductor terminal where a voltage has an opposite sign as a derivative of a current out of the second inductor terminal In one example, the T-coil 200 also includes a bridge capacitance C_{B} 230 across the first terminal 201 and the second terminal 202. In one example, the bridge capacitance C_{B} 230 may be a parasitic capacitance. In one example, the T-coil 200 may be used for broadband matching in an I/O circuit.

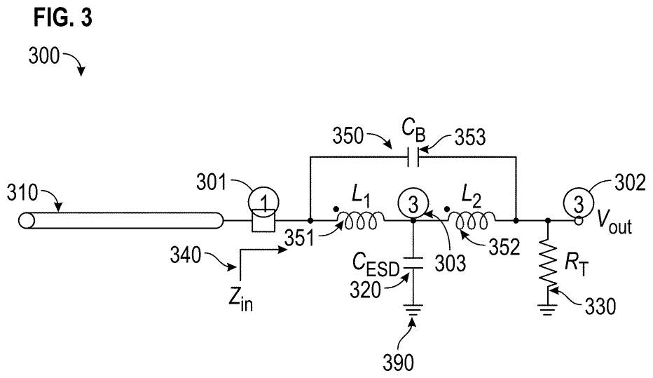

FIG. 3 illustrates an example network 300 of an input/output (I/O) circuit with electrostatic discharge (ESD) protection and a T-coil. For example, an input signal from a signal source may be conveyed on transmission line 310 which may be terminated by a combination of an ESD capacitor 320 with capacitance C_{ESD}, an input resistor 330 with resistance R_{T} and a T-coil 350 with a first inductor 351, a second inductor 352 and a bridge capacitance C_{B} 353. For example, a first terminal 301 of the T-coil 350 is connected to the first inductor 351 on a first inductor polarity reference and a second terminal 302 of the T-coil 350 is connected to the second inductor 352 on a second inductor inverse polarity reference. For example, a third terminal 303 of the T-coil 350 is connected to the first inductor 351 on a first inductor inverse polarity reference and to the second inductor 352 on a second inductor polarity reference. For example, the ESD capacitor 320 with capacitance C_{ESD} is connected to the third terminal 303 of the T-coil 350 and to ground 390. For example, an input impedance Zᵢₙ 340 of the network 300 may have a second bandwidth ω₂ which is greater than the first bandwidth ω₁ of the network 100. In another example, an output signal to a signal designation may be conveyed on transmission line 300.

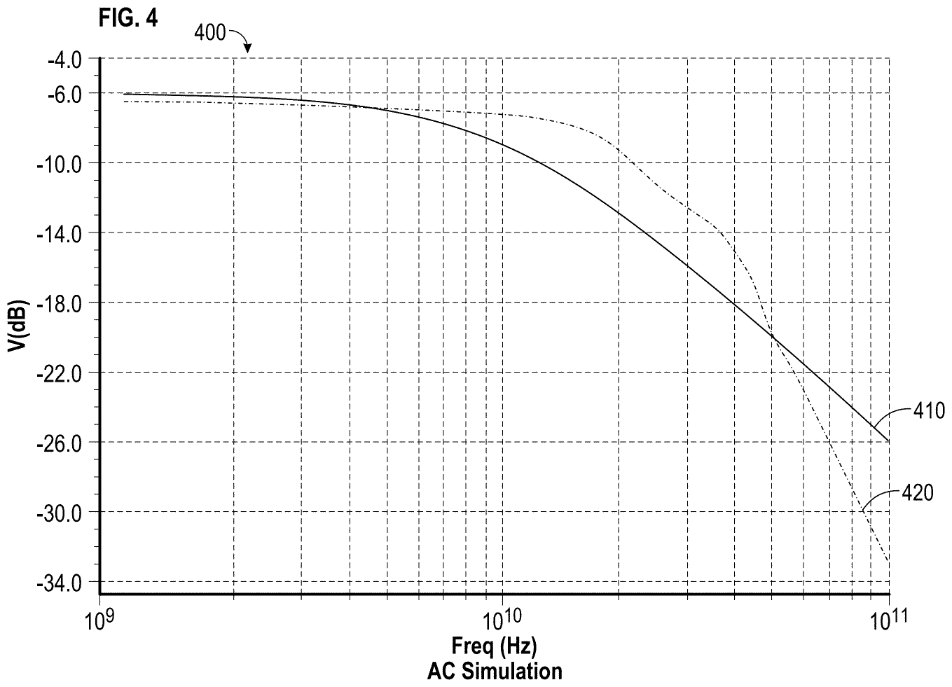

FIG. 4 illustrates an example frequency-domain comparison 400 between a first input/output (I/O) circuit without a T-coil and a second I/O circuit with a T-coil for a signal with 16 gigabit/sec (Gb/s) rate. For example, graph 410 plots a first impedance characteristic (in decibels) vs. frequency (in Hertz) for the first I/O circuit without a T-coil. For example, graph 420 plots a second impedance characteristic for the second I/O circuit with a T-coil. In one example, the first impedance characteristic has a first half-power bandwidth B₁ of approximately 10 GHz and the second impedance characteristic has a second half-power bandwidth B₂ of approximately 20 GHz.

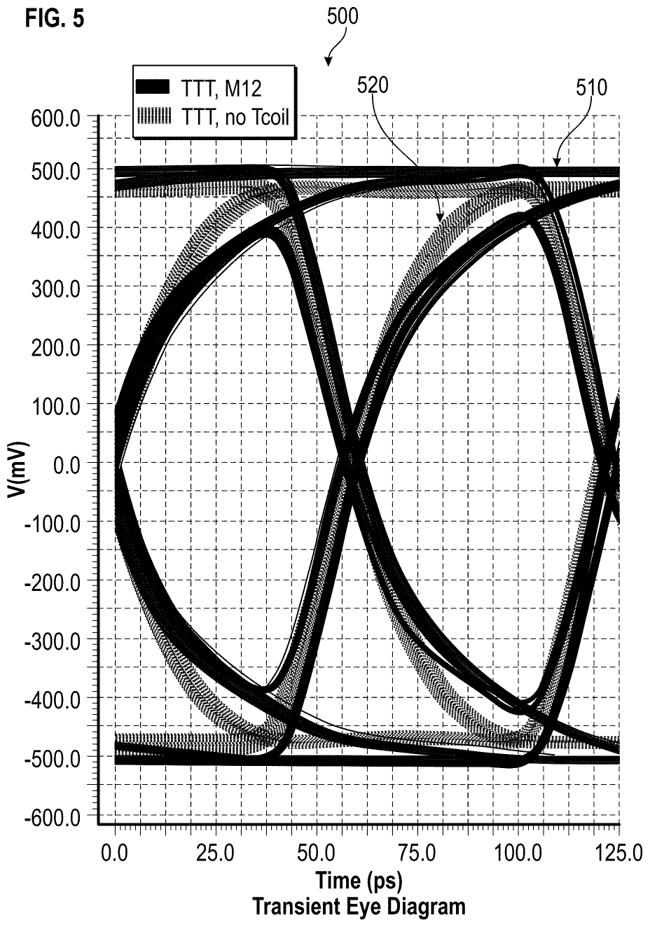

FIG. 5 illustrates an example time-domain comparison 500 between a first I/O circuit without a T-coil and a second I/O circuit with a T-coil for a signal with 16 Gb/s rate. For example, graph 510 plots a first transient eye diagram (in millivolts) vs. time (in picoseconds) for the first I/O circuit without a T-coil. For example, graph 520 plots a second transient eye diagram for the second I/O circuit with a T-coil. In one example, the first transient eye diagram shows a slower transient response compared to the second transient eye diagram. That is, the first transient eye diagram (without the T-coil) has a smaller eye closure than the second transient eye diagram (with the T-coil). In one example, the eye closure is a measure of a maximum voltage difference between positive and negative portions of a signaling waveform. For example, a smaller eye closure is not as desirable as a larger eye closure since the smaller eye closure indicates less noise immunity for the I/O circuit.

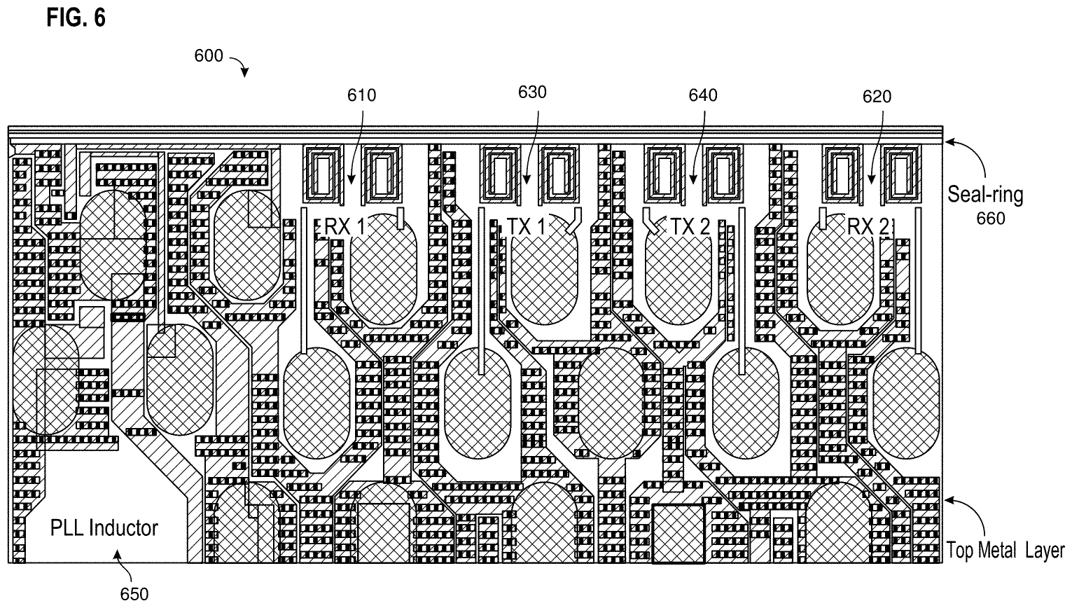

FIG. 6 illustrates an example circuit layout 600 with a plurality of input/output (I/O) circuits. In one example, the I/O circuits may be receive (RX) circuits. The example circuit layout 600 shows only the top metal layer. In one example, the RX circuits may be an input network with T-coils to receive a high rate signal. In one example, the high rate signal may be conveyed by an input transmission line from a signal source. In one example, the I/O circuits may be transmit (TX) circuits. In one example, the TX circuits may be an output network with T-coils to transmit a high rate signal. In one example, the high rate signal may be conveyed on an output transmission line to a signal destination. For example, the circuit layout 600 includes a first RX circuit 610 (labeled as “RX1”), a second RX circuit 620 (labeled as “RX2”), a first TX circuit 630 (labeled as “TX1”) and a second TX circuit 640 (labeled as “TX2”). In one example, the circuit layout 600 includes a phase locked loop (PLL) inductor 650. In one example, the circuit layout 600 includes a seal ring 660. In one example, the seal ring 660 may provide a conductive path between aggressors (e.g., circuits that act as aggressors) and victims (e.g., circuits that act as victims).

In one example, electromagnetic coupling (e.g., inductive coupling) among a plurality of T-coils in the example circuit layout 600 may be severe and may compromise (e.g., degrade) signal integrity. In one example, a TX circuit may act as an aggressor and a RX circuit may act as a victim. For example, an aggressor may be a circuit which is a source of electromagnetic interference (EMI) and a victim may be a circuit which is a recipient of EMI. In one example, EMI from an aggressor to a victim may compromise (e.g., degrade) the performance of the victim. For example, the example circuit layout 600 may have TX circuits and RX circuits in close proximity due to limited spacing (e.g., limited physical spacing). In addition, the example circuit layout 600 may include a seal ring 660 which may provide a conductive path between aggressors and victims. In one example, the seal ring 660 protects edges of the TX circuits and RX circuits.

In one example, electromagnetic coupling among a plurality of T-coils may be quantified by a set of coupling factors. For example, within a T-coil, magnetic fields from a first inductor couple onto a second inductor and magnetic fields from the second inductor couple onto the first inductor. In one example, a first coupling factor K1 within a T-coil (i.e., between a first inductor and a second inductor of the T-coil) quantifies magnetic coupling within the T-coil. For example, between two T-coils, magnetic fields from a first T-coil couple onto a second T-coil and magnetic fields from the second T-coil couple onto the first T-coil. In one example, a second coupling factor K2 between T-coils (i.e., between a first T-coil and a second T-coil) quantifies magnetic coupling between T-coils. In one example, a positive second coupling factor K2 (i.e., K2>0) denotes magnetic field enhancement and a negative second coupling factor K2 (i.e., K2<0) denotes magnetic field cancellation.

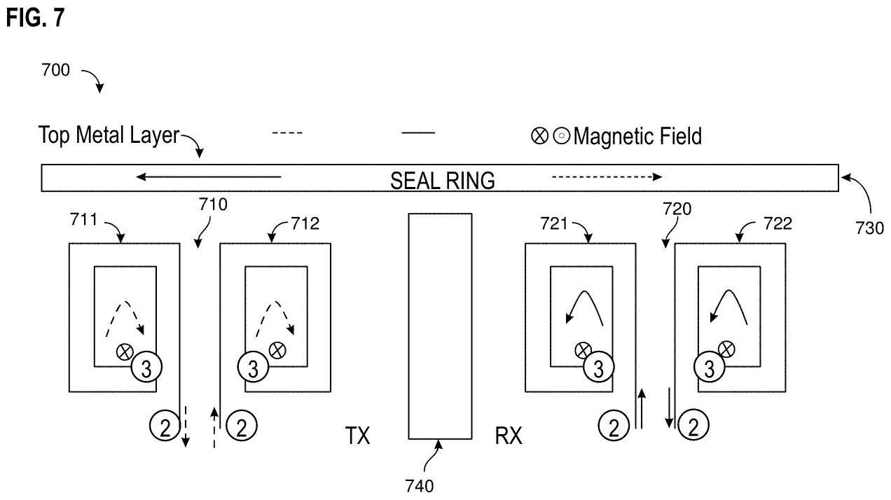

FIG. 7 illustrates a first example T-coil arrangement 700 for an input/output (I/O) circuit. In one example, the T-coil arrangement 700 includes a first pair of T-coils as part of a TX circuit 710 which includes a first transmit T-coil 711 and a second transmit T-coil 712. In one example, the T-coil arrangement 700 includes a second pair of T-coils as part of a RX circuit 720 which includes a first receive T-coil 721 and a second receive T-coil 722. In one example, the first transmit T-coil 711 and the second transmit T-coil 712 are arranged as a symmetric pair. In one example, the symmetric pair may result in a strong electromagnetic coupling effect (e.g., strong interference) onto the RX circuit 720. In one example, the I/O circuit may include a seal ring 730 adjacent to the TX circuit 710 and the RX circuit 720. In one example, the I/O circuit may include a barrier 740 between the TX circuit 710 and the RX circuit 720.

In one example, the barrier 740 isolates the TX circuit 710 and the RX circuit 720. In one example, the seal ring 730 provides a conductive path for electromagnetic coupling from the TX circuit 710 to the RX circuit 720, which degrades isolation. In one example, the TX circuit 710 acts as an aggressor and the RX circuit 720 acts as a victim.

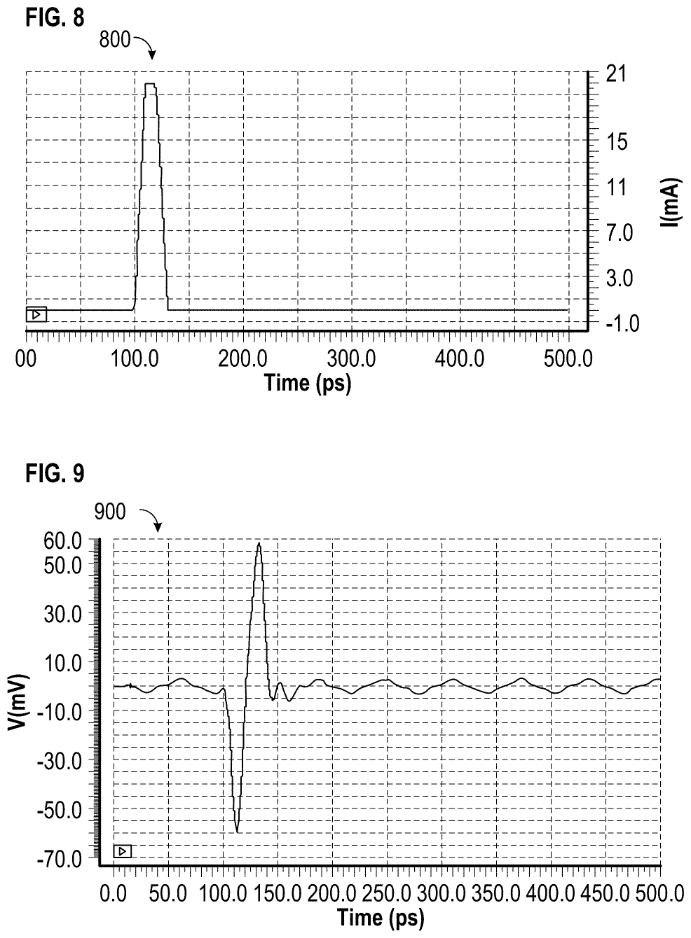

FIG. 8 illustrates an example current graph 800 for an aggressor current pulse with a 20 milliampere (mA) amplitude at a TX circuit. The vertical axis of the current graph 800 is current in units of milliamperes (mA), and the horizontal axis is time in units of picoseconds (ps). In one example, the aggressor current pulse has a rise/fall time of approximately 10 picoseconds (ps) and a pulse width of approximately 10 ps.

FIG. 9 illustrates an example voltage graph 900 for a victim voltage with a +/−60 millivolt induced differential ripple voltage at a RX circuit. The vertical axis of the voltage graph 900 is voltage in units of millivolts (mV), and the horizontal axis is time in units of picoseconds (ps). In one example, the voltage graph 900 corresponds to a complete eye closure in a transient eye diagram for the RX circuit.

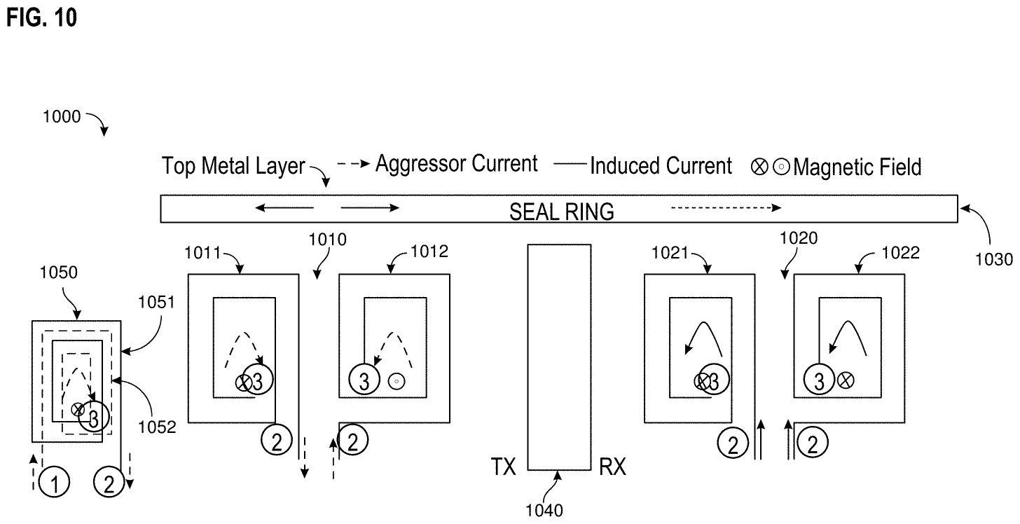

FIG. 10 illustrates a second example T-coil arrangement 1000 for an input/output (I/O) circuit. In one example, the T-coil arrangement 1000 includes a first pair of T-coils as part of a TX circuit 1010 which includes a first transmit T-coil 1011 and a second transmit T-coil 1012. In one example, the T-coil arrangement 1000 includes a second pair of T-coils as part of a RX circuit 1020 which includes a first receive T-coil 1021 and a second receive T-coil 1022. In one example, the first transmit T-coil 1011 and the second transmit T-coil 1012 are arranged as an asymmetric pair. In one example, the first receive T-coil 1021 and the second receive T-coil 1022 are arranged as an asymmetric pair. In one example, the asymmetric pair may result in a reduced electromagnetic coupling effect (e.g., reduced interference) onto the RX circuit 1020. In one example, the I/O circuit may include a seal ring 1030 adjacent to the TX circuit 1010 and the RX circuit 1020. In one example, the I/O circuit may include a barrier 1040 between the TX circuit 1010 and the RX circuit 1020.

In one example, the left side of FIG. 10 illustrates a simplified view for connections of a single T-coil 1050. For example, a solid line 1051 illustrates a first layer of conductive trace from port 2 to port 3 (i.e., second terminal to third terminal). For example, a dashed line 1052 illustrates a second layer of conductive trace from port 3 to port 1 (i.e., third terminal to first terminal). In one example, the first layer and second layer have a positive coupling factor (i.e., magnetic field enhancement).

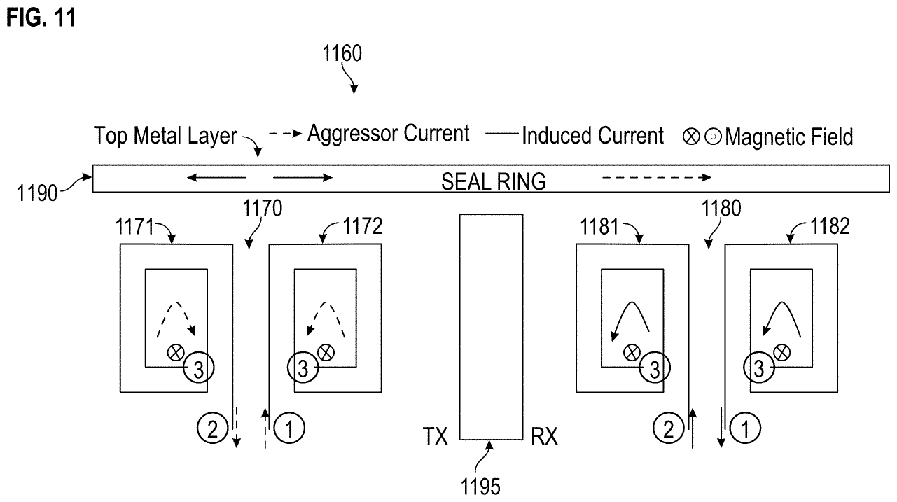

FIG. 11 illustrates a third example T-coil arrangement 1160 for an input/output (I/O) circuit. In one example, the T-coil arrangement 1160 includes a first pair of T-coils as part of a TX circuit 1170 which includes a first transmit T-coil 1171 and a second transmit T-coil 1172. In one example, the T-coil arrangement 1160 includes a second pair of T-coils as part of a RX circuit 1180 which includes a first receive T-coil 1181 and a second receive T-coil 1182. In one example, the first transmit T-coil 1171 and the second transmit T-coil 1172 are arranged as a symmetric pair with first and second terminals of the second transmit T-coil 1172 swapped. In one example, the first receive T-coil 1181 and the second receive T-coil 1182 are arranged as a symmetric pair with first and second terminals of the second receive T-coil 1182 swapped. In one example, the symmetric pair with first and second terminals of the second transmit T-coil 1172 swapped may result in a reduced electromagnetic coupling effect (e.g., reduced interference) onto the RX circuit 1180. In one example, the I/O circuit may include a seal ring 1190 adjacent to the TX circuit 1170 and the RX circuit 1180. In one example, the I/O circuit may include a barrier 1195 between the TX circuit 1170 and the RX circuit 1180.

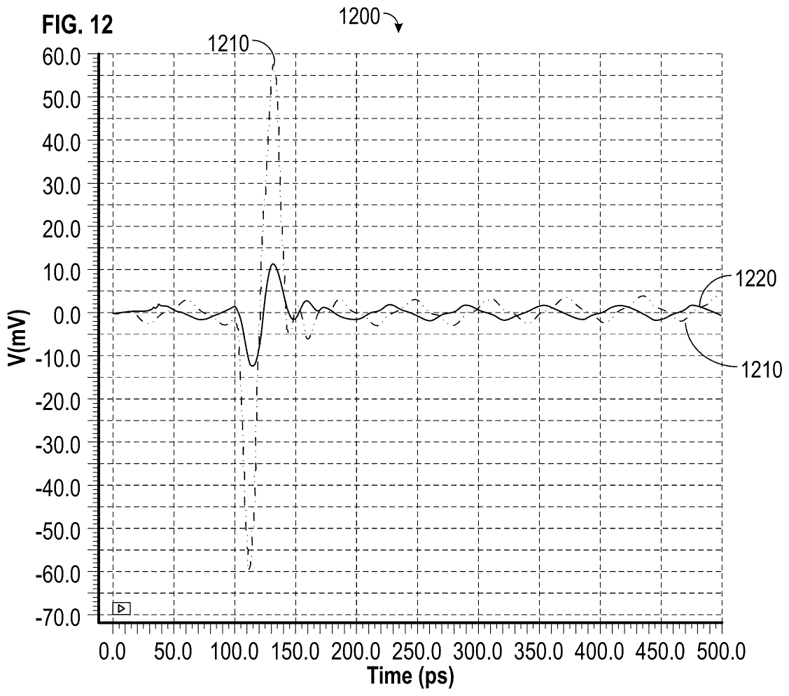

FIG. 12 illustrates an example voltage graph 1200 comparing two T-coil designs. The vertical axis of the voltage graph 1200 is voltage in units of millivolts (mV), and the horizontal axis is time in units of picoseconds (ps). The voltage graph 1200 illustrates two voltage responses at a RX circuit input with an aggressor current pulse in a TX circuit with 20 mA amplitude and 10 ps rise/fall time width. A first voltage response 1210 is a victim voltage of an RX circuit with a T-coil design similar to the T-coil arrangement 800 shown in FIG. 8. For example, the first voltage response 1210 has a peak voltage of approximately 60 mV. A second voltage response 1220 is a victim voltage of an RX circuit with a T-coil design similar to the T-coil arrangement 1100 shown in FIG. 11. For example, the second voltage response 1220 has a peak voltage of approximately 10 mV. In one example, the noise immunity of the T-coil design similar to the T-coil arrangement 1100 relative to that of the T-coil design similar to the T-coil arrangement 800 is approximately 15 dB (i.e., 20 log (60 mV/10 mV). For example, the T-coil design similar to the T-coil arrangement 1100 attenuates noise ripple voltage in the RX circuit due to an aggressor current pulse in the TX circuit.

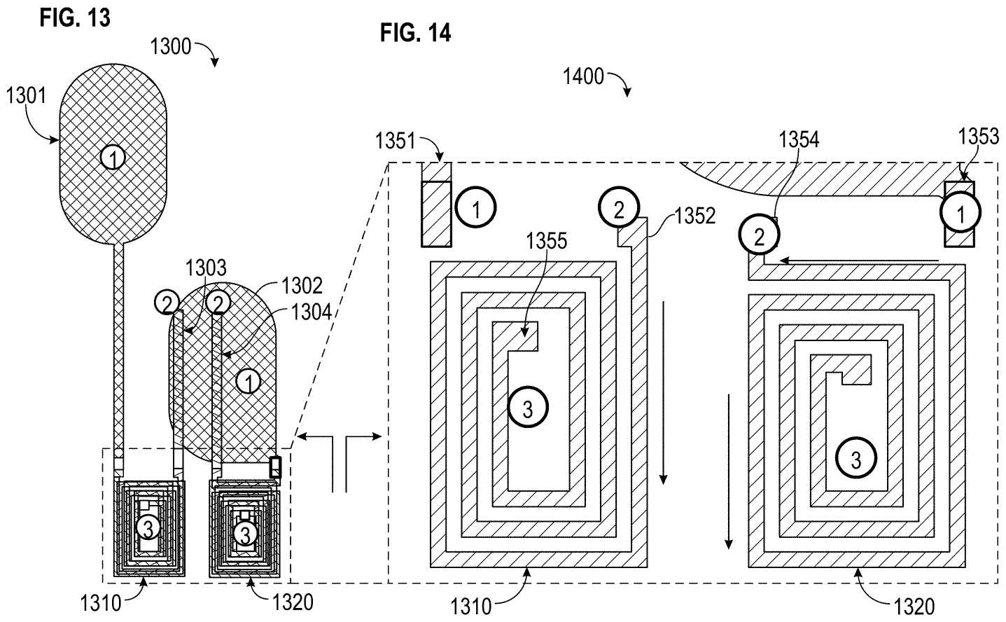

FIG. 13 illustrates a first embodiment of a low noise T-coil design on a circuit layer 1300. In one example, the circuit layer 1300 includes a first T-coil 1310 and a second T-coil 1320. In the first embodiment example, the first T-coil 1310 and the second T-coil 1320 are asymmetric. In one example, asymmetric refers to dissimilar T-coil shapes. In one example, the circuit layer 1300 is an aluminum layer. In another example, the circuit layer 1300 is a metal layer or a conductive layer. In one example, a first bump connection 1301 and a second bump connection 1302 are positioned on an outer side of the circuit layer 1300. In one example, a first circuit interface 1303 and a second circuit interface 1304 are positioned on an inner side of the circuit layer 1300. In one example, the first bump connection 1301 may be used as a first differential interface, and the second bump connection 1302 may be used as a second differential interface.

In FIG. 13, for example, the first bump connection 1301 is connected to a first terminal of the first T-coil 1310 and the first circuit interface 1303 is connected to a second terminal of the first T-coil 1310. For example, the second bump connection 1302 is connected to a first terminal of the second T-coil 1320 and the second circuit interface 1304 is connected to a second terminal of the second T-coil 1320. In one example, a third terminal (not shown) of the first T-coil 1310 and a third terminal (not shown) of the second T-coil 1320 may be positioned according to a design parameter (e.g., desired coupling coefficient of the T-coils). In one example, the first embodiment of a low noise T-coil design on the circuit layer 1300 cancels magnetic fields from the first T-coil 1310 and the second T-coil 1320.

FIG. 14 illustrates an example detailed view of the low noise T-coil design on the circuit layer 1300 shown in FIG. 13. The first T-coil 1310 may be arranged as a spiral inductor with two halves, a first top half and a first bottom half, with a first terminal 1351 connected to the first bottom half and a second terminal 1352 connected to the first top half. In one example, the first terminal 1351 serves as a first input port of the first T-coil 1310 and the second terminal 1352 serves as a first output port of the first T-coil 1310. In one example, the first T-coil 1310 has a first middle node 1355 which connects the first top half and the first bottom half of the first T-coil 1310. In one example, the first T-coil 1310 is located on the circuit layer 1300. In one example, the first input port may be connected to a signal source via a first input transmission line. In one example, the first output port may be connected to a signal destination via a first output transmission line.

The second T-coil 1320 may be arranged as a spiral inductor with two halves: a second top half and a second bottom half. The second T-coil 1320 includes a third terminal 1353 connected to the second top half and a fourth terminal 1354 connected to the second bottom half. In one example, the third terminal 1353 serves as a second input port of the second T-coil 1320 and the fourth terminal 1354 serves as a second output port of the second T-coil 1320. In one example, the second T-coil 1320 is located on the circuit layer 1300. In one example, the second input port may be connected to a signal source via a second input transmission line. In one example, the second output port may be connected to a signal destination via a second output transmission line. In FIGS. 13 and 14, the top metal layer is shown.

In one example, a polarity reference for the first T-coil 1310 is the first terminal 1351 and a polarity reference for the second T-coil 1320 is the fourth terminal 1354. In one example, the first T-coil 1310 has a current flow from the first middle node 1355 to the second terminal 1352 in an outward spiral direction. In one example, the current flow in the outward spiral direction produces a first magnetic field H₁ with a first perpendicular direction out of the circuit layer 1300.

In one example, the second T-coil 1320 has a current flow from the first terminal 1351 to a second middle node 1356 in an inward spiral direction. In one example, the current flow in the inward spiral direction produces a second magnetic field H₂ with a second perpendicular direction into the circuit layer 1300. In one example, the first magnetic field H₁ from the first T-coil 1310 and the second magnetic field H₂ from the second T-coil 1320 are in opposite directions. That is, in one example, the first magnetic field H₁ from the first T-coil 1310 and the second magnetic field H₂ from the second T-coil 1320 cancel each other.

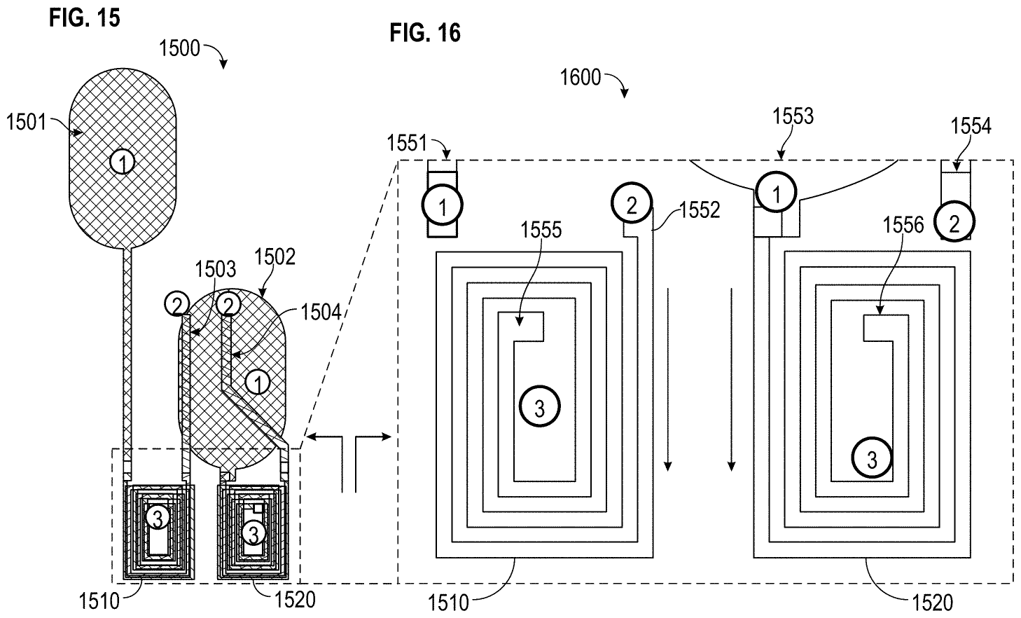

FIG. 15 illustrates a second embodiment of a low noise T-coil design on a circuit layer 1500. In one example, the circuit layer 1500 includes a first T-coil 1510 and a second T-coil 1520. For example, the first T-coil 1510 and the second T-coil 1520 are symmetric. In one example, symmetric refers to similar T-coil shapes. In one example, the circuit layer 1500 is an aluminum layer. In one example, the circuit layer 1500 is a metal layer or a conductive layer. In one example, a first bump connection 1501 and a second bump connection 1502 are positioned on a first side of the circuit layer 1500. In one example, the first bump connection 1501 may be used as a first differential interface, and the second bump connection 1502 may be used as a second differential interface.

In one example, a first circuit interface 1503 and a second circuit interface 1504 are positioned on a second side of the circuit layer 1500. In one example, the first side and the second side are opposite sides (e.g., left side and right side) of the circuit layer 1500. For example, the first bump connection 1501 is connected to a first terminal of the first T-coil 1510, and the first circuit interface 1503 is connected to a second terminal of the first T-coil 1510. For example, the second bump connection 1502 is connected to a first terminal of the second T-coil 1520 and the second circuit interface 1504 is connected to a second terminal of the second T-coil 1520. In one example, a third terminal (not shown) of the first T-coil 1510 and a third terminal (not shown) of the second T-coil 1520 may be positioned according to a design parameter (e.g., desired coupling coefficient of the T-coils). In one example, the second embodiment of the low noise T-coil design on the circuit layer 1500 cancels the magnetic fields from the first T-coil 1510 and the second T-coil 1520.

FIG. 16 illustrates an example detailed view of the low noise T-coil design on the circuit layer 1500 shown in FIG. 15. The first T-coil 1510 may be arranged as a spiral inductor with two halves, a first top half and a first bottom half, with a first terminal 1551 connected to the first bottom half and a second terminal 1552 connected to the first top half. In one example, the first terminal 1551 serves as an input port of the first T-coil 1510 and the second terminal 1552 serves as an output port of the first T-coil 1510. In one example, the first T-coil 1510 has a first middle node 1555 which connects the first top half and the first bottom half of the first T-coil 1510. In one example, the first T-coil 1510 is located on the circuit layer 1500.

The second T-coil 1520 may be arranged as a spiral inductor with two halves, a second top half and a second bottom half, with a third terminal 1553 connected to the second top half and a fourth terminal 1554 connected to the second bottom half. In one example, the third terminal 1553 serves as an input port of the second T-coil 1520 and the fourth terminal 1554 serves as an output port of the second T-coil 1520. In one example, the second T-coil 1520 is located on the circuit layer 1500.

In one example, a polarity reference for the first T-coil 1510 is the first terminal 1551 and a polarity reference for the second T-coil 1520 is the fourth terminal 1554. In one example, the first T-coil 1510 has a current flow from the first middle node 1555 to the second terminal 1552 in an outward spiral direction. In one example, the current flow in the outward spiral direction produces a first magnetic field H₁ with a first perpendicular direction out of the circuit layer 1500.

In one example, the second T-coil 1520 has a current flow from the first terminal 1551 to the second middle node 1556 in an inward spiral direction. In one example, the current flow in the inward spiral direction produces a second magnetic field H₂ with a second perpendicular direction into the circuit layer 1500. In one example, the first magnetic field H₁ from the first T-coil 1510 and the second magnetic field H₂ from the second T-coil 1520 are in opposite directions. That is, in one example, the first magnetic field H₁ from the first T-coil 1510 and the second magnetic field H₂ from the second T-coil 1520 cancel each other.

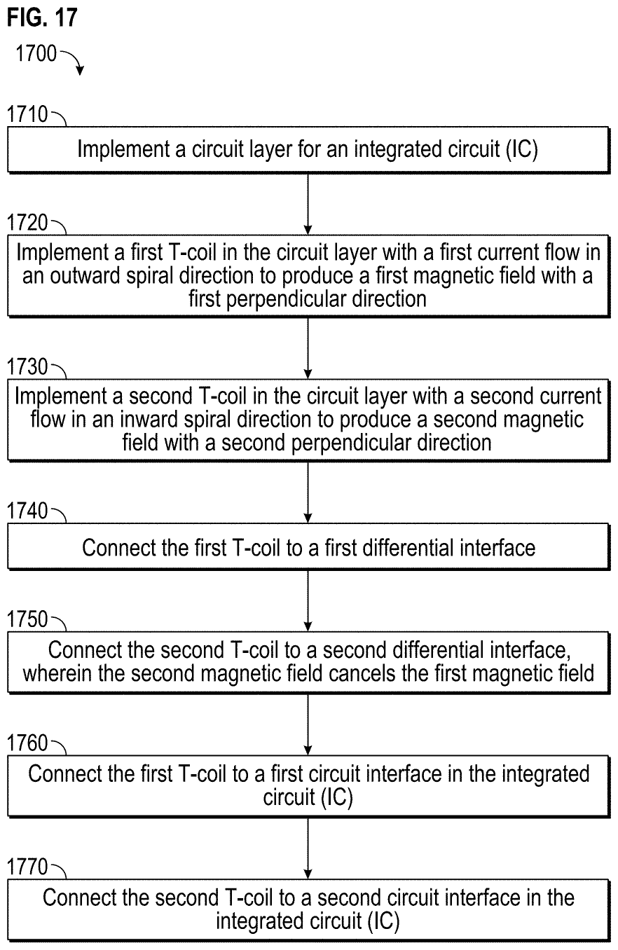

FIG. 17 illustrates an example flow diagram 1700 for implementing a low noise T-coil design. In block 1710, implement a circuit layer for an integrated circuit (IC). In one example, the circuit layer is an aluminum layer. In one example, the circuit layer is a metal layer or a conductive layer. In one example, the circuit layer is a top layer or a bottom layer of the IC.

In block 1720, implement a first T-coil in the circuit layer with a first current flow in an outward spiral direction to produce a first magnetic field with a first perpendicular direction. In one example, the first perpendicular direction is out of the circuit layer. In one example, the first T-coil is arranged as a first spiral inductor. In one example, the first T-coil includes a first top half and a first bottom half. The first T-coil may include a first terminal connected to the first bottom half and may include a second terminal connected to the first top half.

In block 1730, implement a second T-coil in the circuit layer with a second current flow in an inward spiral direction to produce a second magnetic field with a second perpendicular direction. In one example, the second perpendicular direction is into the circuit layer. In one example, the first magnetic field and the second magnetic field are in opposite directions. In one example, the second T-coil is arranged as a second spiral inductor. In one example, the second T-coil includes a second top half and a second bottom half. The second T-coil may include a first terminal connected to the second bottom half and may include a second terminal connected to the second top half.

In block 1740, connect the first T-coil to a first differential interface. In one example, the first T-coil is connected via a first bump connection to the first differential interface. In one example, the first differential interface serves as a first input port. In one example, the first input port is connected to a signal source via a first input transmission line. The first differential interface may serve as a first output port. In one example, the first output port is connected to a signal destination via a first output transmission line.

In block 1750, connect the second T-coil to a second differential interface, wherein the second magnetic field cancels the first magnetic field. In one example, the second T-coil is connected via a second bump connection to the second differential interface. In one example, the second differential interface serves as a second input port. In one example, the second input port is connected to a signal source via a second input transmission line. The second differential interface may serve as a second output port. In one example, the second output port is connected to a signal destination via a second output transmission line.

In block 1760, connect the first T-coil to a first circuit interface in the integrated circuit (IC). In one example, the first circuit interface is connected to a first load interface.

In block 1770, connect the second T-coil to a second circuit interface in the integrated circuit (IC). In one example, the second circuit interface is connected to a second load interface.

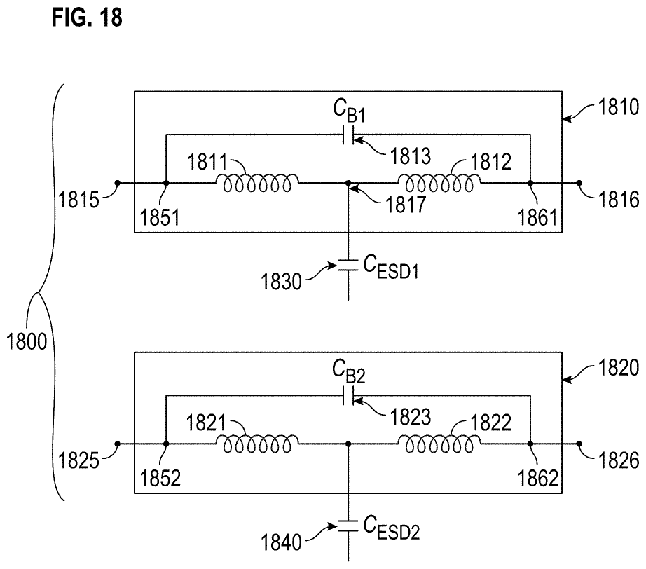

FIG. 18 illustrates an example electrical schematic diagram for an input/output (I/O) circuit 1800 with ESD protection and a low noise T-coil design. In one example, the I/O circuit 1800 includes a first T-coil 1810 and a second T-coil 1820. In one example, the I/O circuit 1800 includes a differential interface between the first T-coil 1810 and the second T-coil 1820. In one example, the I/O circuit 1800 includes a first input port 1851 and a second input port 1852. In one example, the first input port 1851 and the second input port 1852 are connected to a signal source via an input transmission line. In one example, the I/O circuit includes a first output port 1861 and a second output port 1862. In one example, the first output port 1861 and the second output port 1862 are connected to a signal destination via an output transmission line.

In one example, the first T-coil 1810 has a first terminal 1815, a second terminal 1816 and a third terminal 1817. In one example, the first terminal 1815 is a polarity reference for the first T-coil 1810. In one example, the second terminal 1816 is an inverse polarity reference for the first T-coil 1810. In one example, the third terminal 1817 is a first middle node for the first T-coil 1810.

In one example, the first T-coil 1810 includes a first inductor 1811 connected to the first terminal 1815 and a second inductor 1812 connected to the second terminal 1816. In one example, the first inductor 1811 and the second inductor 1812 are connected at the third terminal 1817. In one example, the first T-coil 1810 includes a first bridge capacitor (C_{B1}) 1813 connected to the first terminal 1815 and the second terminal 1816. In one example, the first bridge capacitor (C_{B1}) 1813 is a first parasitic capacitor. In one example, the first T-coil 1810 is connected to a first ESD capacitor (C_{ESD1}) 1830. In one example, the first ESD capacitor (Cn_{ESD1}) 1830 is connected to the first T-coil 1810 at the third terminal 1817.

In one example, the second T-coil 1820 has a fourth terminal 1825, a fifth terminal 1826 and a sixth terminal 1827. In one example, the fifth terminal 1826 is a polarity reference for the second T-coil 1820. In one example, the fourth terminal 1825 is an inverse polarity reference for the second T-coil 1820. In one example, the sixth terminal 1827 is a second middle node for the second T-coil 1820.

In one example, the second T-coil 1820 includes a third inductor 1821 connected to the fourth terminal 1825 and a fourth inductor 1822 connected to the fifth terminal 1826. In one example, the third inductor 1821 and the fourth inductor 1822 are connected at the sixth terminal 1827. In one example, the second T-coil 1820 includes a second bridge capacitor (C_{B2}) 1823 connected to the fourth terminal 1825 and the fifth terminal 1826. In one example, the second bridge capacitor (C_{B2}) 1823 is a second parasitic capacitor. In one example, the second T-coil 1820 is connected to a second ESD capacitor (C_{ESD2}) 1840. In one example, the second ESD capacitor (C_{ESD2}) 1840 is connected to the second T-coil 1820 at the sixth terminal 1827.

In one example, the improved low noise T-coil design relies on cancellation of induced voltage from nearby T-coils. On the transmit side, differential driving circuit generates a low emitted coupled voltage due to magnetic field cancellation which results in reduced induced current to nearby circuit elements. On the receive side, coupled voltage generator by an aggressor transmitter will generate only common-mode induced current or voltage which is suppressed by the victim receiver.

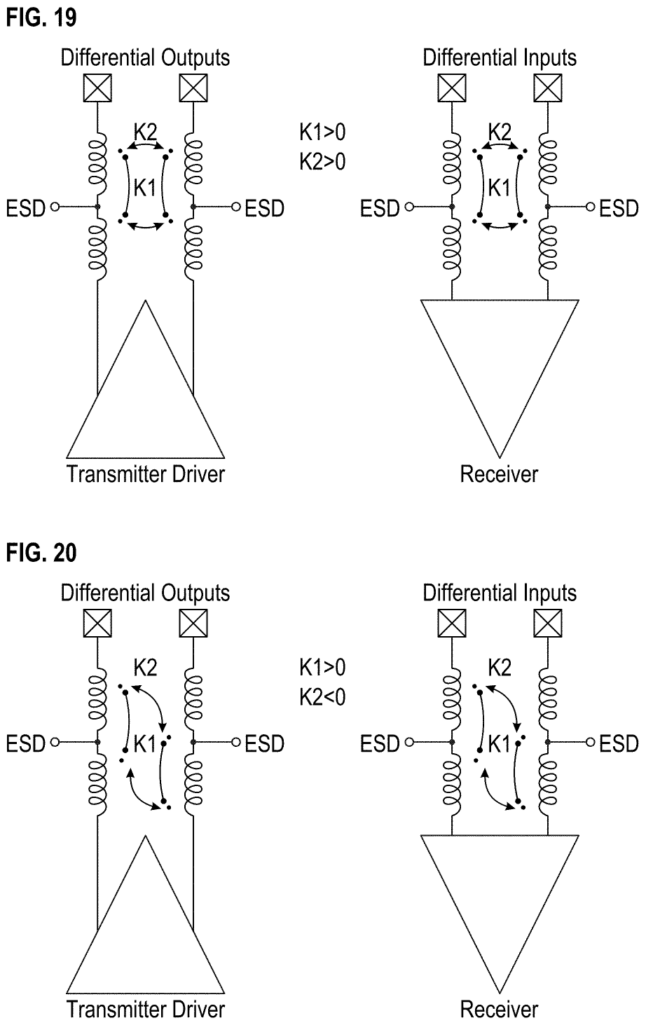

FIG. 19 illustrates an example schematic diagram 1900 for the first example T-coil arrangement 800 shown in FIG. 8. For example, a transmitter driver 1910 (i.e., TX circuit) includes a first transmit T-coil 1911 and a second transmit T-coil 1912. For example, a receiver 1920 (i.e., RX circuit) includes a first receive T-coil 1921 and a second receive T-coil 1922. In one example, a first coupling factor K1 within a T-coil is positive and a second coupling factor K2 between T-coils is positive (i.e., magnetic enhancement).

FIG. 20 illustrates an example schematic diagram for the second example T-coil arrangement shown in FIG. 11a and the third example T-coil arrangement shown in FIG. 11b. For example, a transmitter driver 2010 (i.e., TX circuit) includes a first transmit T-coil 2011 and a second transmit T-coil 2012. For example, a receiver 2020 (i.e., RX circuit) includes a first receive T-coil 2021 and a second receive T-coil 2022. In one example, a first coupling factor K1 within T-coils is positive and a second coupling factor K2 between T-coils is negative (i.e., magnetic field cancellation).

In one aspect, one or more of the steps for providing a low noise T-coil design in FIG. 17 may be executed by one or more processors which may include hardware, software, firmware, etc. In one aspect, one or more of the steps in FIG. 17 may be executed by one or more processors which may include hardware, software, firmware, etc. The one or more processors, for example, may be used to execute software or firmware needed to perform the steps in the flow diagram of FIG. 17. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise.

Any circuitry included in the processor(s) is merely provided as an example, and other means for carrying out the described functions may be included within various aspects of the present disclosure, including but not limited to the instructions stored in the computer-readable medium, or any other suitable apparatus or means described herein, and utilizing, for example, the processes and/or algorithms described herein in relation to the example flow diagram.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. For instance, a first die may be coupled to a second die in a package even though the first die is never directly physically in contact with the second die. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features and/or functions illustrated in the figures may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the figures may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.”

What is claimed is:

1. An input/output (I/O) circuit comprising:
a first T-coil, wherein the first T-coil includes a first set of two inductors connected to each other in series arranged to accommodate a first current flow to produce a first magnetic field with a first perpendicular direction; and
a second T-coil, wherein the second T-coil includes a second set of two inductors connected to each other in series arranged to accommodate a second current flow to produce a second magnetic field with a second perpendicular direction; and
wherein the second magnetic field cancels the first magnetic field.

2. The input/output (I/O) circuit of claim 1, further comprising:
a first middle node located between two inductors of the first set of two inductors; and
a first electrostatic discharge (ESD) capacitor coupled to the first T-coil at the first middle node.

3. The input/output (I/O) circuit of claim 2, further comprising:
a second middle node located between two inductors of the second set of two inductors; and
a second electrostatic discharge (ESD) capacitor coupled to the second T-coil at the second middle node.

4. The input/output (I/O) circuit of claim 3, wherein the first T-coil further comprises a first bridge capacitor connected in parallel to the first set of two inductors.

5. The input/output (I/O) circuit of claim 4, wherein the second T-coil further comprises a second bridge capacitor connected in parallel to the second set of two inductors.

6. The input/output (I/O) circuit of claim 5, wherein the first T-coil further comprises a first terminal and a second terminal, wherein the first terminal is a polarity reference for the first T-coil and the second terminal is an inverse polarity reference for the first T-coil.

7. The input/output (I/O) circuit of claim 6, wherein the first bridge capacitor is connected to the first terminal and the second terminal.

8. The input/output (I/O) circuit of claim 7, wherein the second T-coil further comprises a third terminal and a fourth terminal, wherein the third terminal is a polarity reference for the second T-coil and the fourth terminal is an inverse polarity reference for the second T-coil.

9. The input/output (I/O) circuit of claim 8, wherein the second bridge capacitor is connected to the third terminal and the fourth terminal.

10. A method for implementing a low noise T-coil design comprising:
implementing a first T-coil in a circuit layer with a first current flow in an outward spiral direction to produce a first magnetic field with a first perpendicular direction;
implementing a second T-coil in the circuit layer with a second current flow in an inward spiral direction to produce a second magnetic field with a second perpendicular direction;
connecting the first T-coil to a first differential interface; and
connecting the second T-coil to a second differential interface, wherein the second magnetic field cancels the first magnetic field.

11. The method of claim 10, further comprising implementing the circuit layer for an integrated circuit (IC).

12. The method of claim 11, wherein the circuit layer is a conductive layer.

13. The method of claim 12, wherein the circuit layer is an aluminum layer.

14. The method of claim 11, further comprising:
connecting the first T-coil to a first circuit interface; and
connecting the second T-coil to a second circuit interface.

15. The method of claim 14, wherein the first circuit interface is connected to a first load interface.

16. The method of claim 15, wherein the second circuit interface is connected to a second load interface.

17. The method of claim 15, wherein the first perpendicular direction is out of the circuit layer and the second perpendicular direction is into the circuit layer.

18. The method of claim 17, wherein the first T-coil is arranged as a first spiral inductor.

19. The method of claim 18, wherein the first T-coil includes a first top half and a first bottom half, and wherein the first T-coil includes a first terminal connected to the first bottom half and includes a second terminal connected to the first top half.

20. The method of claim 18, wherein the second T-coil is arranged as a second spiral inductor.

21. The method of claim 20, wherein the second T-coil includes a second top half and a second bottom half, and wherein the second T-coil includes a first terminal connected to the second bottom half and includes a second terminal connected to the second top half.

22. The method of claim 10, wherein the first T-coil is connected to the first differential interface via a first bump connection.

23. The method of claim 22, wherein the first differential interface serves as a first input port.

24. The method of claim 23, wherein the first input port is connected to a signal source via a first input transmission line.

25. The method of claim 22, wherein the first differential interface serves as a first output port.

26. The method of claim 25, wherein the first output port is connected to a signal destination via a first output transmission line.
